(19) United States
(12) Patent Application Publication
(10) Pub. No.: US 2010/0048021 A1
(43) Pub. Date: Feb. 25, 2010

(54) SEMICONDUCTOR DEVICE MANUFACTURING METHOD

(76) Inventor: Takatoshi ONO, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/511,718

(22) Filed: Jul. 29, 2009

(30) Foreign Application Priority Data
Aug. 22, 2008 (JP) 2008-214312

(51) Int. Cl. H01L 21/306; H01L 21/311; H01L 21/3065

(52) U.S. Cl. 438/692; 438/703; 438/712; 257/E21.249; 257/E21.218; 257/E21.23

(57) ABSTRACT

A region corresponding to a convex pattern of a first insulating film deposited above a semiconductor substrate having a plurality of convex patterns is removed by anisotropic etching up to a top surface of the convex patterns, the convex patterns are exposed, and a convex portion of the first insulating film is formed. Subsequently, a second insulating film is deposited above the semiconductor substrate, the convex portion of the first insulating film and the second insulating film that covers the convex portion are removed to a surface height of the second insulating film at least on the convex patterns by a CMP process to perform planarization.

### CROSS-REFERENCE TO RELATED APPLICATIONS

This application is based upon and claims the benefit of priority from the prior Japanese Patent Application No. 2008-214312, filed on Aug. 22, 2008; the entire contents of which are incorporated herein by reference.

### BACKGROUND OF THE INVENTION

1. Field of the Invention

The present invention relates to a semiconductor device manufacturing method.

2. Description of the Related Art

Formation of a pre metal dielectric (PMD) in a manufacturing process of a semiconductor device is performed by covering convex steps formed in an underlying layer to deposit an insulating film and polishing and removing the insulating film by chemical mechanical polishing (CMP), so that the insulating film having a predetermined thickness is left on the convex steps. For the deposition film thickness of the insulating film in this case, there is required a thick film thickness obtained by adding the height of the convex steps, a polishing amount in CMP, and a residual film thickness to be left on the convex portion.

When the insulating film is thick, a concave region between the convex steps is blocked by the insulating film in a portion where the convex steps are densely formed, and this results in an insulating-film pattern (hereinafter, “large-area insulating film pattern”) having an overall large-area convex portion. Meanwhile, in a portion where the convex steps are sparsely formed, blocking of the concave region between the convex steps does not occur, resulting in an insulating-film pattern (hereinafter, “small-area insulating film pattern”) having a small-area convex portion with a similar shape to that of each of the convex steps. Thus, when the large-area insulating film pattern and the small-area insulating film pattern are mixed, the planarization of the insulating film by CMP becomes difficult, and deterioration in planarity occurs.

Accordingly, as a method of preventing such deterioration in planarization by CMP, Japanese Patent Application Laid-open No. 2007-48980 proposes a method in which planarization is performed by CMP after an insulating film of a portion corresponding to a convex steps is removed by a photolithography technique and reactive ion etching (RIE), for example.

However, even the above technique has a problem that when there is a portion where an insulating film is blocked, the planarization by CMP becomes difficult, and the convex step is left after a CMP process. It is thus desired to etch also the portion where the insulating film is blocked by RIE. However, for the etching, a blocked location needs to be previously calculated by a design of the pattern of convex steps formed in the underlying layer, a film thickness or film-forming characteristics of the insulating film or the like. In this case, RIE is performed by using a dedicated mask. Besides, the blocked location is shifted by a design change of the pattern of the convex steps, a change of types of the film, a change of the film thickness or the like, and thus in these cases, a mask for RIE needs to be changed.

There is also a problem in terms of controlling the residual film thickness after the CMP process. When the insulating film is thick, the film thickness after deposition can be varied. In this case, the film thickness of the insulting film after an RIE process is also varied. In the RIE process, etching is stopped somewhere within the insulating film without using a stopper, and thus control of the etching amount is difficult. Particularly, the convex steps formed in the underlying layer can be exposed, and thus thinning of the residual film is difficult.

In view of these problems, the deposition film thickness of the insulating film is set thick so that a milling allowance in CMP is secured even when the film thickness of the insulating film after the RIE process is varied. As a result, there is a problem that the insulting film is more easily blocked. Further, the insulting film is milled by CMP to a target film thickness from the thick film thickness, and thus there are problem such that the polishing amount in CMP becomes large, the load increases, and the deterioration in planarity occurs. Therefore, it is difficult to form an insulting film having favorable planarity with a desired film thickness.

### BRIEF SUMMARY OF THE INVENTION

According to one aspect of the present invention, a semiconductor device manufacturing method includes depositing a first insulating film above a semiconductor substrate on which a plurality of convex patterns are located; exposing the convex patterns and forming a convex portion formed of the first insulating film by removing the first insulating film in a region corresponding to a top surface of the convex patterns by anisotropic etching using the top surface of the convex patterns as a stopper; depositing a second insulating film above the semiconductor substrate in a manner to cover the convex patterns and the convex portion formed of the first insulating film; and forming an insulating layer having the second insulating film deposited on the convex patterns and the first insulating film deposited on a region between the adjacent convex patterns by removing the convex portion formed of the first insulating film and the second insulating film that covers the convex portion to a surface height of the second insulating film at least on the convex patterns by a CMP process to perform planarization.

### BRIEF DESCRIPTION OF THE DRAWINGS

FIG. 1A to FIG. 1G are cross-sectional views for explaining a semiconductor device manufacturing method according to an embodiment of the present invention;

FIG. 2 is a schematic diagram of a configuration of a polishing device that performs a planarizing process of an insulating film by applying the semiconductor device manufacturing method according to the embodiment;

FIG. 3 is a schematic characteristic chart of a relation between a time and a current value of a motor that rotates a polishing plate when a surface of a semiconductor substrate is polished by CMP, by applying the semiconductor device manufacturing method according to the embodiment;

FIG. 4 is a cross-sectional view for explaining a state that a concave step is formed in a region next to an underlying convex steps;

FIG. 5A to FIG. 5C are cross-sectional views for explaining a method of forming a mask of which an aperture pattern size is reduced, in the semiconductor device manufacturing method according to the embodiment; and

FIG. 6 is a cross-sectional view of a state after RIE using a second resist pattern as a mask, in the semiconductor device manufacturing method according to the embodiment.

### DETAILED DESCRIPTION OF THE INVENTION

Exemplary embodiments of a semiconductor device manufacturing method according to the present invention will be explained below in detail with reference to the accompanying drawings. The present invention is not limited to the following embodiment, and various modifications carried out without departing from the scope of the invention are also included therein. In addition, for facilitating understanding, scales of respective members may differ from those of actual products. The same applies to the relations between the drawings.

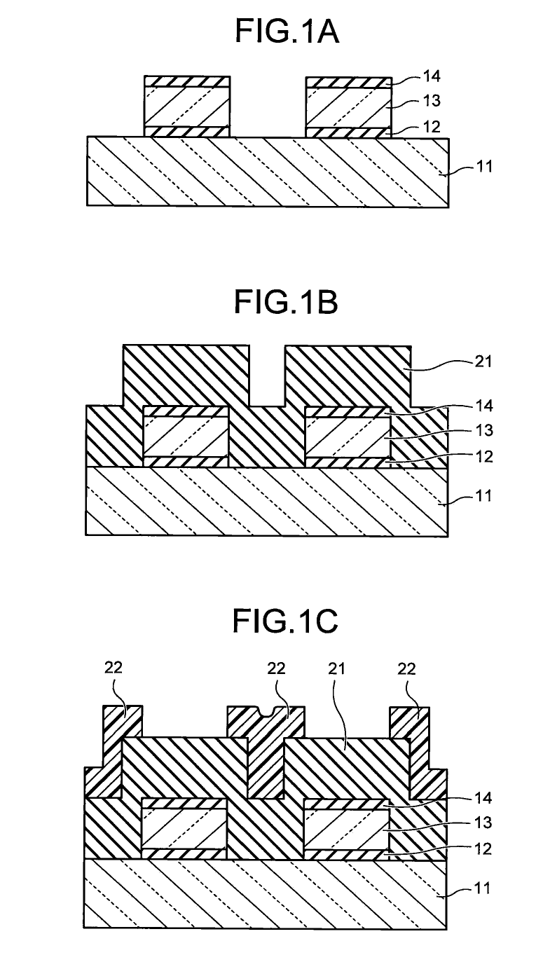

A method of forming a PMD to which a semiconductor device manufacturing method according to an embodiment of the present invention is applied is explained with reference to FIG. 1A to FIG. 1G. FIGS. 1A to 1G are cross-sectional views for explaining the semiconductor device manufacturing method according to the embodiment.

First, on a semiconductor substrate 11, a plurality of transistor elements are formed. That is, on the semiconductor substrate 11, a gate electrode 13 formed of a polysilicon film is formed via a gate insulating film 12 formed of a silicon oxide film. On the gate electrode 13, a stopper film 14 formed of a silicon nitride film is formed (FIG. 1A). Accordingly, on the semiconductor substrate 11, underlying convex patterns formed of a plurality of underlying convex steps in which the gate insulating film 12, the gate electrode 13, and the stopper film 14 are stacked is formed. The semiconductor substrate 11 is formed with a source-drain region. However, because this region is not directly relevant to the semiconductor device manufacturing method according to the present embodiment, explanations thereof will be omitted.

On the entire surface of the semiconductor substrate 11, as a first insulating film 21, a silicon oxide film is deposited by a chemical vapor deposition (CVD) method, for example (FIG. 1B). At this time, the film thickness dimension of the first insulating film 21 is set as a thin film thickness substantially equal to the height dimension from a surface of the semiconductor substrate 11 to a surface of the stopper film 14, which is the height of the underlying convex steps. That is, a concave region of the first insulating film 21, which is a region on a concave portion between the adjacent underlying convex steps, is set in height substantially equal to the underlying convex steps.

When the film thickness of the first insulating film 21 is thinned as described above, even when transistors are densely formed and thus an interval between the adjacent gate electrodes 13 is narrow, an increase (bottom-up) of the height of the concave region between the adjacent underlying convex steps is suppressed after the first insulating film 21 is deposited on the concave region. This eliminates the removing of the first insulating film 21 at a blocked portion in a process of removing the first insulating film 21 mentioned below. Thus, calculation for specifying the blocked portion and a mask for removing the first insulating film 21 at the blocked portion become unnecessary.

Next, a mask 22 on the first insulating film 21 is formed by lithography, etching or the like (FIG. 1C). The mask 22 is patterned with a pattern having an opening region corresponding to a portion of the first insulating film 21 to be removed, is formed of a photoresist film, for example, and serves to remove the portion of the first insulating film 21. In this case, the mask 22 having a pattern obtained by opening a region corresponding to the top surface of the underlying convex step is formed. When forming the mask 22, a photomask used when forming the underlying convex steps can be used, and any dedicated photomask is not necessary.

Subsequently, by RIE using the mask 22, a portion of the first insulating film 21 is removed by using the stopper film 14, as a stopper, formed on an uppermost layer of the underlying convex steps (FIG. 1D). In this case, the stopper film 14 is made of a material having large etching selectivity with respect to the first insulating film 21 in RIE, and thus the etching of the first insulating film 21 is stopped at a time when the stopper film 14 is exposed. By the RIE, the first insulating film 21 of the region corresponding to the top surface of the underlying convex steps is all removed. As described above, when the stopper film 14 is used, controlling the etching amount is not necessary in the etching of the first insulating film 21, and thus it becomes easy to control etching. Even when the stopper film 14 is not formed in the uppermost layer of the underlying convex steps, as long as the uppermost layer of the underlying convex steps is made of a material having large etching selectivity with respect to the first insulating film 21 in RIE, the same effect can be achieved.

The film thickness of the first insulating film 21 is set to be substantially equal to the height of the underlying convex steps. Therefore, after etching by RIE, a minute convex portion formed of the first insulating film 21 is formed in the contour of the pattern of the underlying convex steps, and thus the height of the concave region of the first insulating film 21 and that of the underlying convex steps are set to be substantially equal.

Thereafter, the mask 22 is removed (FIG. 1E), and on the entire surface of the semiconductor substrate 11, as a second insulting film 23, a silicon oxide film is deposited by a CVD method, for example (FIG. 1F). The film thickness of the second insulating film 23 is substantially equal to a desired film thickness intended to be finally left on the underlying convex steps, i.e., a film thickness intended to be left on the stopper film 14. Further, on the assumption of polishing by CMP, the film thickness can also be obtained by adding a polishing amount in CMP to the desired film thickness intended to be finally left on the underlying convex steps.

When the film thickness of the second insulating film 23 is thus set as the desired film thickness finally required, the film thickness of the second insulating film 23 can be thinned. Thus, the concave region between the minute convex portions on a surface of the first insulating film 21 is not blocked. Even after the deposition of the second insulating film 23, the minute convex portion in which the second insulating film 23 is deposited in the minute convex portion on the surface of the first insulating film 21 independently remains in the contour of the pattern of the underlying convex steps. This makes it possible to reduce the size of the individual areas of the convex portion on a surface of the second insulating film 23, thereby reducing the prevalence of the convex portion of the second insulating film 23, and also to reduce a load at a CMP process in a subsequent process.

The second insulating film 23 can be made of the same material as that of the first insulating film 21, and can also be made of a material different from that of the first insulating film 21. However, when forming a contact hole reaching the semiconductor substrate 11 in a subsequent process of manufacturing a semiconductor device, for example, in order that the second insulating film 23 and the first insulating film 21 can be etched easily in the same process, the second insulating film 23 and the first insulating film 21 are preferably made of the same material.

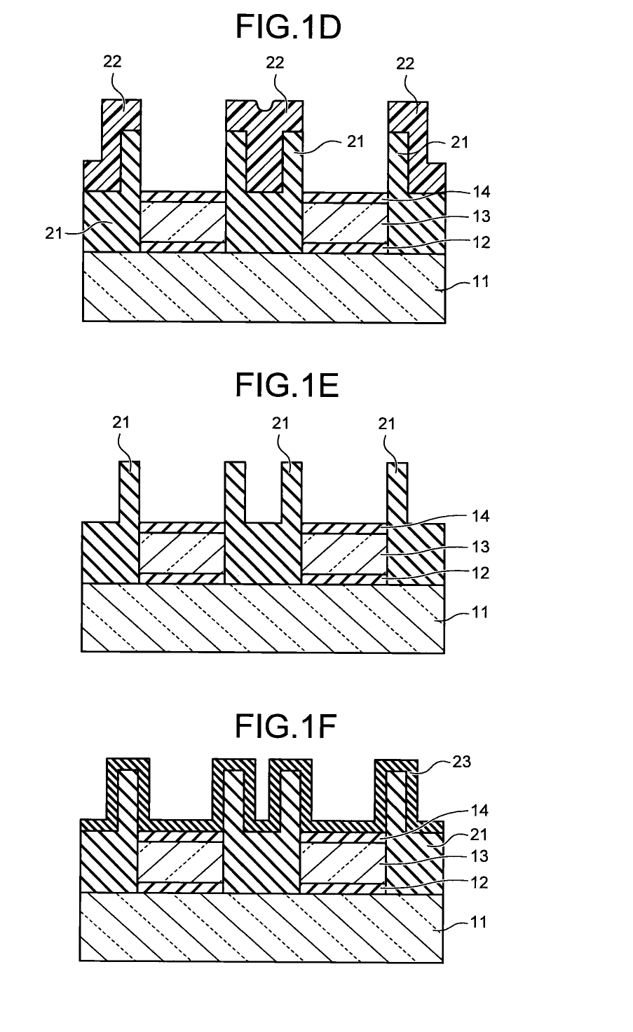

Thereafter, the CMP using a polishing device as shown in FIG. 2, for example, is employed to polish and remove the minute convex portion formed of the second insulating film 23 and the first insulating film 21 to planarize the surface of the semiconductor substrate 11. FIG. 2 is a schematic diagram for explaining a configuration of a polishing device that performs a process of planarizing the insulating film of the surface of the semiconductor substrate 11 by applying the semiconductor device manufacturing method according to the present embodiment.

The polishing device includes a polishing plate (a polishing table) 31 that can be rotated by a motor, a polishing pad 32 affixed on the polishing plate 31, a vacuum chuck holder 33 that is located above the polishing plate 31 and that can be rotated by a motor, and a polishing-liquid supplying pipe 34 which is connected to a polishing liquid tank and of which the discharge unit protrudes to near the polishing pad 32. The semiconductor substrate 11, which is a target to be polished, is vacuum chucked to the vacuum chuck holder 33 so that a surface to be polished faces the polishing pad 32. The polishing-liquid supplying pipe 34 includes a unit (not shown) that controls a supply amount of the polishing liquid.

The film thickness of the second insulating film 23 is previously set to the desired film thickness intended to be finally left on the underlying convex steps. Accordingly, during the CMP, it suffices to polish and remove the minute convex portion formed of the second insulating film 23 and the first insulating film 21 formed in the contour of the pattern of the underlying convex steps for relaxing. Thus, the load in the CMP process is lessened and the polishing becomes easy, the planarization can be performed with a small polishing amount, and thus favorable planarization can be realized. Further, under the assumed condition of polishing by CMP, when the film thickness of the second insulating film 23 is formed as a film thickness obtained by adding some polishing amounts in CMP to a desired film thickness intended to be finally left on the underlying convex steps, the surface of the second insulating film 23 and the first insulating film 21 after the polishing of the minute convex portion formed of the second insulating film 23 and the first insulating film 21 is polished by a predetermined thickness for planarization. Also in this case, the thickness by which the surface of the second insulating film 23 and the first insulating film 21 after the polishing of the minute convex portion is polished is small, and thus the polishing becomes easy, and the planarization can be performed with a small polishing amount.

In the CMP, it is preferable to selectively polish the minute convex portion formed of the second insulating film 23 and the first insulating film 21 and polish the concave region of the second insulating film 23 by such a polishing characteristic that the polishing amount is reduced as much as possible. For this reason, the polishing pad 32 is suitably made from a resin raw material such as urethane. The progress state of polishing, that is, the relaxed state of the minute convex portion in the middle of the polishing process can be monitored by a current value (that is obtained while polishing is in progress) of a motor that rotates the polishing plate 31 or a current value (that is obtained while polishing is in progress) of a motor that rotates the vacuum chuck holder 33 by utilizing the fact that a contact area between the presently-polished insulating-film surface and the polishing pad 32 is changed.

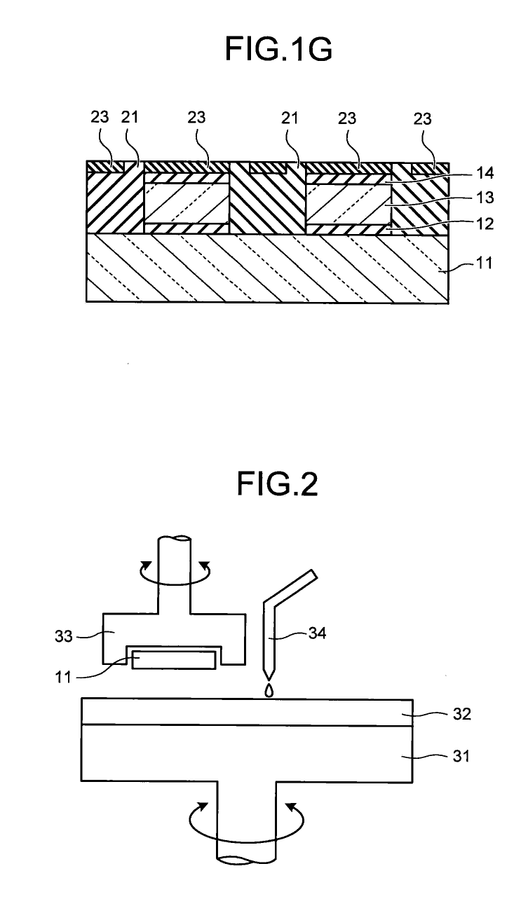

The polishing device performs polishing by rotating each of the polishing plate 31 and the vacuum chuck holder 33. During the polishing, the polishing device controls the number of rotations by adjusting a current value of a motor so that a predetermined set number of rotations is maintained. FIG. 3 is a schematic characteristic chart of a relation between a time and a current value of the motor that rotates the polishing plate 31, when the surface of the insulating film is polished by CMP. FIG. 3 depicts the relation between a time and a current value of the motor that rotates the polishing plate 31, and a motor that rotates the vacuum chuck holder 33 also exhibits a similar tendency with respect to a current value and a time.

As shown in FIG. 3, at the time of starting polishing, by the entanglement between the corner of the minute convex portion and the polishing pad 32, a frictional resistance between the insulating film surface and the polishing pad 32 is large, and the current value of the motor is also large. When this entanglement is canceled, the frictional resistance between the insulating film surface and the polishing pad 32 becomes small because the contact area between the polishing surface and the polishing pad 32 is small. Thus, the motor that rotates the polishing plate 31 can rotate the polishing plate 31 with a small current value to maintain the predetermined number of rotations. Similarly, the motor that rotates the vacuum chuck holder 33 can rotate the vacuum chuck holder 33 with a small current value to maintain a predetermined number of rotations.

Thereafter, the polishing is progressed, the minute convex portion is removed, and that portion ceases to exist. At this time, the contact area between the insulating film surface and the polishing pad 32 becomes large, and the frictional resistance between the insulating film surface and the polishing pad 32 becomes large. Thus, the current value of the motor that rotates the polishing plate 31 suddenly becomes large. Subsequently, the minute convex portion is removed and ceases to exist, and when the surface of the insulating film becomes plain, the current value of the motor becomes constant.

Accordingly, by monitoring the current value (that is obtained while polishing is in progress) of the motor that rotates the polishing plate 31 or the current value (that is obtained while polishing is in progress) of the motor that rotates the vacuum chuck holder 33, and when the current value becomes constant after the sudden change in current value is ended, it becomes possible to determine that the relaxing of the minute convex portion is ended. Accordingly, it becomes possible to easily and surely control when CMP is stopped, and possible to leave the second insulating film 23 of a desired film thickness on the underlying convex steps.

The use of the method enables the formation of a PMD that is an insulating layer having the second insulating film 23 deposited on the underlying convex patterns and the first insulating film 21 deposited on the region between the adjacent underlying convex patterns and that has favorable planarity in which the variation of the film thickness is suppressed (FIG. 1G). The residual film thickness of the insulating film left on the underlying convex steps in the obtained PMD is a deposition film thickness of the second insulating film 23 or a film thickness obtained by subtracting a polishing amount in CMP from the deposition film thickness of the second insulating film 23.

After etching by RIE (FIG. 1D), because the height of the concave region of the first insulating film 21 and that of the underlying convex steps are substantially equal, a large difference is not generated in the height of the deposition surface of the second insulating film 23 between on the concave region of the first insulating film 21 and on the underlying convex steps. Thus, also when the surface of the second insulating film 23 is polished by CMP, the polishing amount can be reduced to a very small amount, and as a result, the residual film thickness of the insulating film left on the underlying convex steps after CMP is substantially the same as the deposition film thickness of the film thickness of the second insulating film 23. In CMP, the second insulating film 23 on the underlying convex steps is scarcely polished, and thus the underlying convex steps is not exposed and thinning of the insulting film to be left on the underlying convex steps can be implemented.

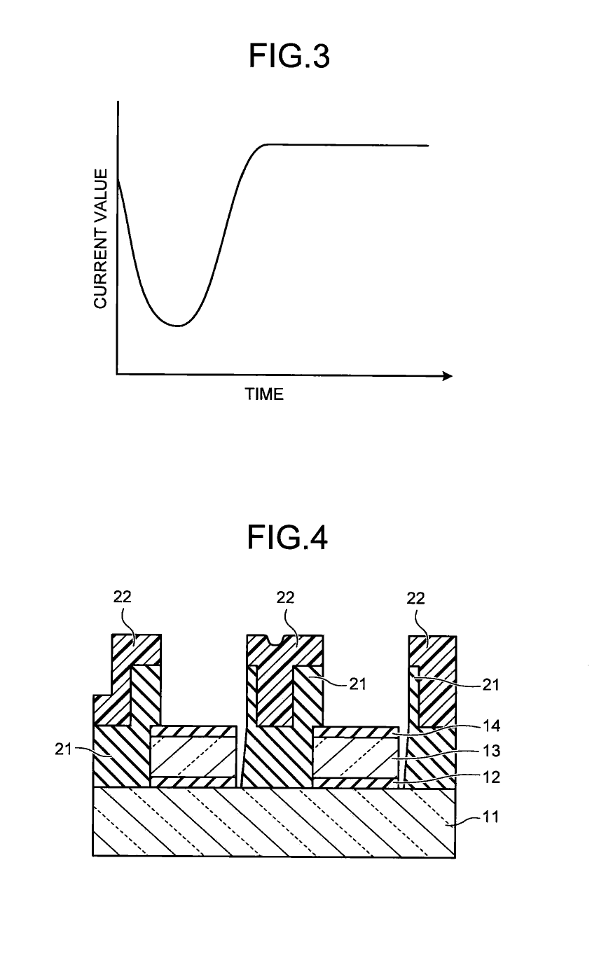

In the implementation, the mask 22 is formed on the first insulating film 21 by lithography, etching or the like (FIG. 1C). When the formation position of the mask 22 is deviated, a region where the stopper film 14 is not formed is etched as shown in FIG. 4, and as a result, a concave step is formed in a region next to the underlying convex steps. FIG. 4 is a cross-sectional view for explaining a state that the concave step is formed in a region next to the underlying convex steps.

As a countermeasure to the above problem, it is preferable that an aperture pattern size of the mask 22 is reduced, and thereby, even when the formation position of the mask 22 is deviated, the etched region of the first insulating film 21 does not come out of the stopper film 14. Reduction of the aperture pattern size of the mask 22 can be realized by using a dedicated photomask of which the aperture pattern size is reduced when forming the mask 22, rather than using a photomask used when forming the underlying convex steps.

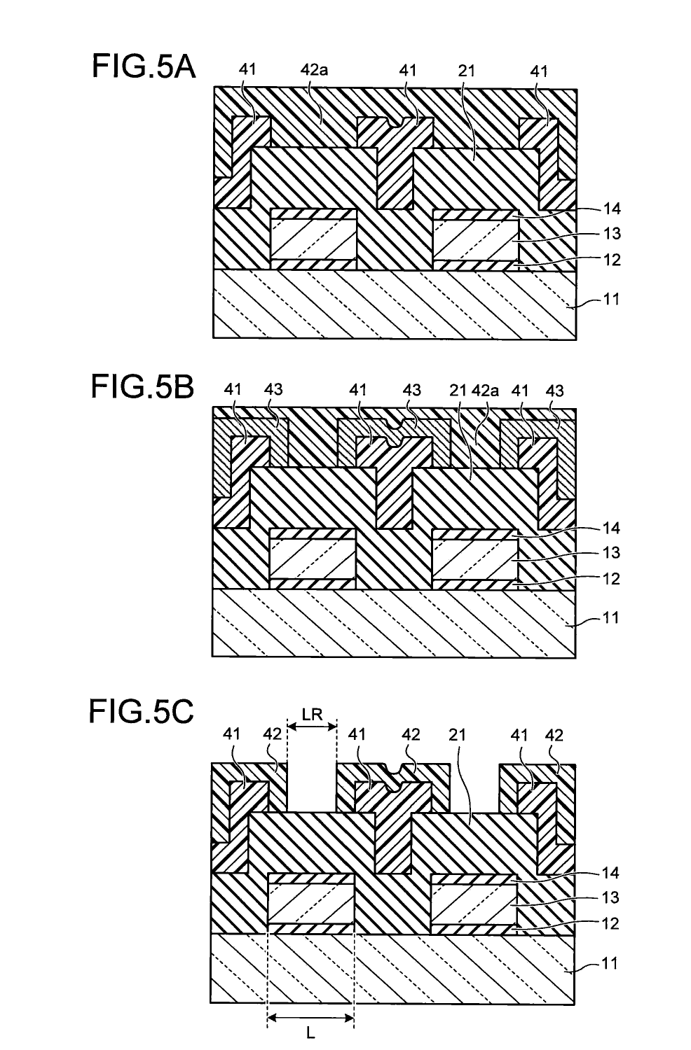

Further, the aperture pattern size can be reduced by forming a new mask that covers the mask 22. A method of reducing the aperture pattern size of the mask 22 is explained below with reference to FIG. 5A to FIG. 5C. FIG. 5A to FIG. 5C are cross-sectional views for explaining a method of forming a mask of which the aperture pattern size is reduced.

In this case, the mask 22 is formed as a first resist pattern 41 by using a first resist in which an acid component is generated inside by an appropriate heating process, for example. Examples of such a first resist include a positive resist configured by a novolac resin and naphthoquinone diazido-based photosensitizer.

Subsequently, as shown in FIG. 5A, onto the semiconductor substrate 11, a second resist that includes a crosslinkable material that crosslinks under the presence of acid and that is dissolved in a solvent in which the resist of the first resist pattern 41 is not dissolved is applied to form a second resist layer 42a. As long as the second resist can be applied uniformly on the first resist pattern 41, any method can be used as the method of applying the second resist.

Subsequently, a heating process is applied to the first resist pattern 41 formed on the semiconductor substrate 11 and the second resist layer 42a formed thereon to promote the diffusion of acid from the first resist pattern 41, which is supplied to within the second resist layer 42a, thereby generating a crosslinking reaction at the interface between the second resist layer 42a and the first resist pattern 41. As a result, as shown in FIG. 5B, a crosslinking layer 43 in which the crosslinking reaction occurs is formed within the second resist layer 42a so that the first resist pattern 41 is coated.

Thereafter, as shown in FIG. 5C, by using water or an alkali aqueous solution such as tetramethylammonium hydroxide (TMAH) as a developer, an uncrosslinked portion of the second resist layer 42a is developed and peeled off, thereby forming a second resist pattern 42. As a result of the processes, the aperture pattern size of the mask 22 (the first resist pattern 41) is reduced, and the second resist pattern 42 having an aperture diameter LR shorter than a length L of the underlying convex steps in a gate-length direction of the gate electrode 13 can be formed.

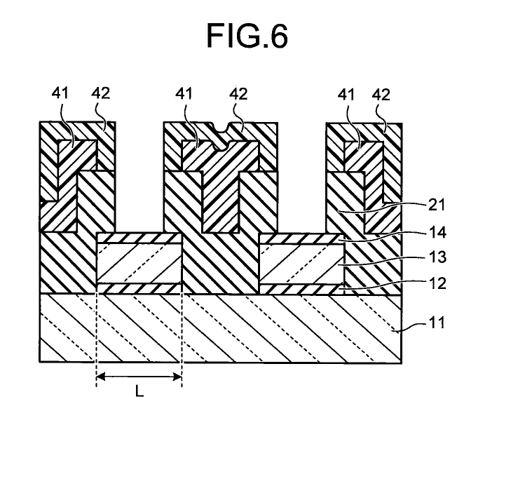

Subsequently, as shown in FIG. 6, by RIE in which such the second resist pattern 42 is used as a mask, a portion of the first insulating film 21 is removed by a pattern more downsized than the underlying convex steps. FIG. 6 is a cross-sectional view of a state after RIE using the second resist pattern 42 as a mask. When performing RIE using, as a mask, the second resist pattern 42 of which the aperture pattern size is thus reduced, even when a slight alignment deviation is generated at the time of the lithography for the mask formation, it is possible to prevent the concave step from being formed in a region next to the underlying convex steps, as shown in FIG. 4.

As described above, in the present embodiment, after the deposition of the first insulating film 21, the first insulating film 21 on the underlying convex steps is removed until the underlying convex steps is exposed, and from thereon, the second insulating film 23 is deposited, and the minute convex portion formed on the surface is polished and removed by CMP for planarization. By performing these processes, control of the residual film thickness of the insulting film left on the underlying convex steps can be performed by the deposition film thickness of the second insulating film 23. That is, when the second insulating film 23 is deposited with a desired film thickness intended to be finally left on the underlying convex steps, control of the residual film thickness of the insulating film left on the underlying convex steps is enabled. Further, it suffices that in the CMP process for the insulating film, the minute convex portion formed of the second insulating film 23 and the first insulating film 21 are only polished and removed for relaxing. As a result, the load in the CMP process is lessened, the polishing becomes easy, and the planarization is possible with a small polishing amount. Accordingly, favorable planarity can be realized.

Therefore, according to the semiconductor device manufacturing method of the present embodiment, the residual film thickness of the insulating film left on the underlying convex steps can be controlled to a desirable film thickness highly accurately and easily, and the PMD having favorable planarity can be easily formed with a desired film thickness. In addition, thinning of the residual film thickness of the insulating film left on the underlying convex steps and the PMD can be achieved.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device manufacturing method, comprising:
depositing a first insulating film above a semiconductor substrate on which a plurality of convex patterns are located;
exposing the convex patterns and forming a convex portion formed of the first insulating film by removing the first insulating film in a region corresponding to a top surface of the convex patterns by anisotropic etching using the top surface of the convex patterns as a stopper;
depositing a second insulating film above the semiconductor substrate in a manner to cover the convex patterns and the convex portion formed of the first insulating film; and
forming an insulating layer having the second insulating film deposited on the convex patterns and the first insulating film deposited on a region between the adjacent convex patterns by removing the convex portion formed of the first insulating film and the second insulating film that covers the convex portion to a surface height of the second insulating film at least on the convex patterns by a CMP process to perform planarization.

2. The semiconductor device manufacturing method according to claim 1, wherein a film thickness dimension of the first insulating film is substantially the same as a height dimension of the convex patterns.

3. The semiconductor device manufacturing method according to claim 2, wherein a height of the first insulating film on a concave region between the adjacent convex patterns is substantially the same as a height dimension of the convex patterns.

4. The semiconductor device manufacturing method according to claim 1, wherein in the anisotropic etching, the first insulating film in the region corresponding to the top surface of the convex patterns is removed by a pattern more downsized than the convex patterns.

5. The semiconductor device manufacturing method according to claim 1, wherein the first insulating film and the second insulating film are made of a same material.

6. The semiconductor device manufacturing method according to claim 1, wherein the convex patterns have a film used as a stopper for the anisotropic etching on the top surface thereof.

7. The semiconductor device manufacturing method according to claim 6, wherein the anisotropic etching is reactive ion etching (RIE).

8. The semiconductor device manufacturing method according to claim 7, wherein the film used as a stopper is made of a material having large etching selectivity with respect to the first insulating film in RIE.

9. The semiconductor device manufacturing method according to claim 8, wherein the film used as a stopper is a silicon nitride film.

10. The semiconductor device manufacturing method according to claim 1, wherein a mask of a pattern in which the region corresponding to the top surface of the convex patterns is opened is formed above the first insulating film, and the anisotropic etching is performed by using the mask as an etching mask.

11. The semiconductor device manufacturing method according to claim 10, wherein the mask is formed of a photoresist film.

12. The semiconductor device manufacturing method according to claim 11, wherein the mask is formed by using a photomask that is used to form the convex patterns.

13. The semiconductor device manufacturing method according to claim 12, wherein the mask is used as an etching mask upon reduction of an aperture pattern size.

14. The semiconductor device manufacturing method according to claim 1, wherein the convex patterns includes a pattern configured by a transistor element.

15. The semiconductor device manufacturing method according to claim 1, wherein the first insulating film is a silicon oxide film.

16. The semiconductor device manufacturing method according to claim 1, wherein the second insulating film is deposited by a film thickness to be left on the convex patterns after the CMP process.

17. The semiconductor device manufacturing method according to claim 1, wherein the second insulating film is deposited by a film thickness obtained by adding a film thickness to be left on the convex patterns after the CMP process and a polishing film thickness in the CMP process.

18. The semiconductor device manufacturing method according to claim 1, wherein in the CMP process, a polishing pad made of urethane resin is used.

19. The semiconductor device manufacturing method according to claim 1, wherein in the CMP process, by a current value of a motor that rotates a polishing plate or by a current value of a motor that rotates the semiconductor substrate, when relatively sliding a polishing pad placed on the polishing plate and a formation surface of the convex patterns on the semiconductor substrate, a progress state of polishing by the CMP process is monitored.

20. The semiconductor device manufacturing method according to claim 19, wherein the CMP process is finished at a time when the current value of the motor becomes substantially constant after rising.
